(19) United States
(12) Patent Application Publication
(10) Pub. No.: US 2025/0047070 A1
(43) Pub. Date: Feb. 6, 2025

(54) RESONANCE MODULE, SILICON-BASED EXTERNAL CAVITY CHIP, LASER, AND LASER RADAR

(71) Applicant: Wuhan VanJee Optoelectronic Technology Co., Ltd., Wuhan (CN)

(72) Inventors: Boqing ZHANG, Wuhan (CN); Shiqi HE, Wuhan (CN); Yihui LIU, Wuhan (CN); Yang XU, Wuhan (CN); Yongqiang DENG, Wuhan (CN)

(73) Assignee: Wuhan VanJee Optoelectronic Technology Co., Ltd., Wuhan (CN)

(21) Appl. No.: 18/918,112

(22) Filed: Oct. 17, 2024

Related U.S. Application Data
(63) Continuation of application No. PCT/CN2024/102759, filed on Jun. 29, 2024.

(30) Foreign Application Priority Data
Jun. 30, 2023 (CN) 202310799150.2

(51) Int. Cl. H01S 5/14; H01S 5/10

(52) U.S. Cl. CPC H01S 5/14; H01S 5/101

(57) ABSTRACT

The present disclosure is applicable to a field of laser radar technology and provides a resonance module, a silicon-based external cavity chip, a laser, and a laser radar. The resonance module includes multiple main resonators and at least one auxiliary resonator, both of the main resonators and the auxiliary resonator are tunable micro-ring resonators; the multiple main resonators are cascaded in sequence through a connecting module to form a cascaded structure, and a vernier effect can be formed between two adjacent main resonators; when an auxiliary resonator is provided for matching the main resonator, coupling of the main resonator and the auxiliary resonator that are provided in a matching manner expands a free spectrum range of the main resonator. The tunable range of lasers applied to the laser radar and improve the scanning angle of the laser radar can be expanded.

### CROSS-REFERENCE TO RELATED APPLICATION

This application is a continuation of International Application No. PCT/CN2024/102759, filed on Jun. 29, 2024, which claims priority to Chinese Patent Application No. 202310799150.2, filed on Jun. 30, 2023 to the China National Intellectual Property Administration and entitled “RESONANCE MODULE, SILICON-BASED EXTERNAL CAVITY CHIP, LASER, AND LASER RADAR”. These applications are incorporated by reference in their entireties.

### TECHNICAL FIELD

The present disclosure belongs to a field of laser radar technology, and in particular relates to a resonance module, a silicon-based external cavity chip, a laser, and a laser radar.

### BACKGROUND

At present, the application of external cavity semiconductor lasers is becoming increasingly widespread, and there are mainly two solutions for their implementation: one is an external cavity structure comprised by discrete components such as etalons and diffraction gratings, and the other is a quasi monolithic integrated external cavity structure of the silicon-based photonic chip. Among them, diffraction grating external cavity laser has a wide tunable range and extremely narrow linewidth, however, it has large volume, difficult optical path alignment, complex packaging, and low mechanical tuning efficiency, which will reduce the reliability of the laser to some extent; a silicon-based narrow linewidth external cavity laser integrates a gain chip with a monolithic silicon-based external cavity chip, which has the wide tunable characteristic and the narrow linewidth characteristic of the external cavity structure, as well as a low power consumption and high reliability characteristics of the monolithic integrated structure.

As a major advantage of silicon-based external cavity lasers, the wavelength tunable range is usually wider than other types of integrated lasers. Currently, most silicon-based external cavity lasers can cover the communication C-band range (1525 nm-1565 nm), while also maintaining a high side-mode suppression ratio and narrow linewidth, this corresponds to the basic requirement for tunable lasers in modern optical communication systems. However, with the rapid development of recent technologies such as optical phased array (OPA), there is a requirement for a wider tunable range of on-chip integrated lasers. Therefore, silicon-based external cavity lasers still need to further expand their tunable ranges while maintaining a narrow linewidth and a high side-mode suppression ratio.

### SUMMARY

The purpose of the present disclosure is to provide a resonance module, a silicon-based external cavity chip, a laser, and a laser radar, with the aim of further expanding the tunable range of a laser applied to the laser radar.

The present disclosure is implemented in the following manner. In a first aspect, a resonance module is provided, which includes multiple main resonators and at least one auxiliary resonator, where both of the main resonators and the auxiliary resonator are tunable micro-ring resonators; the multiple main resonators are cascaded in sequence through a connecting module to form a cascaded structure, and a vernier effect can be formed between two adjacent main resonators; when an auxiliary resonator is provided for matching the main resonator, coupling of the main resonator and the auxiliary resonator that are provided in a matching manner expands a free spectrum range of the main resonator.

In some embodiments, the cascaded structure is a two-level cascaded structure including a first main resonator and a second main resonator; the auxiliary resonator is provided with one and is provided for matching the first main resonator; where there is a length difference between a cavity length of the first main resonator and a cavity length of the second main resonator, and the cavity length of the first main resonator and the cavity length of the second main resonator are both integer multiples of the length difference; a free spectrum range of the auxiliary resonator is twice as much as a free spectrum range of the first main resonator.

In some embodiments, a cavity length of the auxiliary resonator is ½ of the cavity length of the first main resonator.

In some embodiments, the cascaded structure includes 3 or more of the main resonators being cascaded in sequence, differences between cavity lengths of every two adjacent main resonators are different.

In some embodiments, when the cascaded structure is an N level cascaded structure, where N is an integer greater than 1, the resonance module receives two input light beams from an external input; where one input light beam enters into the resonance module through an input port of a first level main resonator, and after passing through N main resonators in sequence, is coupled out from the resonance module through an download port of an Nth level main resonator; the other input light beam is inputted into the resonance module through the download port of the Nth level main resonator, and after passing through the N main resonators in sequence, is coupled out from the resonance module by the input port of the first level main resonator.

In some embodiments, the connecting module includes: a waveguide; or a combination structure of a waveguide and one main resonator.

In a second aspect, a silicon-based external cavity chip is provided, which includes an input coupler, a directional coupler, a resonance module and an output coupler; where the resonance module includes: multiple main resonators and at least one auxiliary resonator, where both of the main resonators and the auxiliary resonator are tunable micro-ring resonators;
the multiple main resonators are cascaded in sequence through a connecting module to form a cascaded structure, and a vernier effect can be formed between two adjacent main resonators;
when an auxiliary resonator is provided for matching the main resonator, coupling of the main resonator and the auxiliary resonator that are provided in a matching manner expands a free spectrum range of the main resonator;
where the input coupler is configured to couple a light signal provided by an external light source into the silicon-based external cavity chip;
the directional coupler receives the light signal and provides the light signal to the resonance module, the light signal is selected by the resonance module, the selected light signal is coupled out through the directional coupler and the output coupler in sequence.

In some embodiments, the directional coupler is a 2×2 directional coupler;
where the light signal received by a first port of the directional coupler is divided into two input light beams in the directional coupler; where one input light beam is coupled into the resonance module through a second port of the directional coupler and a first port of the resonance module in sequence, is coupled into the directional coupler through a second port of the resonance module and a third port of the directional coupler after passing through a cascaded structure of the resonance module, and is provided to the output coupler by a fourth port of the directional coupler; the other input light beam is coupled into the resonance module through the third port of the directional coupler and the second port of the resonance module in sequence, is coupled into the directional coupler through the first port of the resonance module and the second port of the directional coupler after passing through the cascaded structure of the resonance module, and is provided to the output coupler by the fourth port of the directional coupler.

In some embodiments, the silicon-based external cavity chip further includes a phase shifter connected between the input coupler and the first port of the directional coupler.

In a third aspect, a silicon-based external cavity chip is provided, which includes an input coupler, a resonance module and a Sagnac ring; the resonance module includes: multiple main resonators and at least one auxiliary resonator, where both of the main resonators and the auxiliary resonator are tunable micro-ring resonators;
the multiple main resonators are cascaded in sequence through a connecting module to form a cascaded structure, and a vernier effect can be formed between two adjacent main resonators;
when an auxiliary resonator is provided for matching the main resonator, coupling of the main resonator and the auxiliary resonator that are provided in a matching manner expands a free spectrum range of the main resonator;
where the input coupler is configured to couple light signals provided by an external light source into the silicon-based external cavity chip;
a first port of the resonance module is coupled to the input coupler through a waveguide, a second port of the resonance module is couple to the Sagnac ring.

In a fourth aspect, a silicon-based external cavity laser is provided, which includes a light source and the silicon-based external cavity chip provided by a respective embodiment described above, where the light resource is configured to provide a light signal to the silicon-based external cavity chip.

In a fifth aspect, a laser radar is provided, which includes a laser module, a transmission module, a detection module, a detection module, and a data processing module, where the laser module includes a silicon-based external cavity laser provided by a respective embodiment described above.

The technical effect of the present disclosure compared to the prior art is that: adopting a resonance module provided in the first aspect, which includes multiple main resonators and at least one auxiliary resonator, the multiple main resonators are cascaded in sequence through a connecting module to form a cascaded structure, and a vernier effect can be formed between two adjacent main resonators; when an auxiliary resonator is provided for matching the main resonator, utilizing the coupling of the main resonator and the auxiliary resonator that are provided in a matching manner, a free spectrum range of the main resonator can be expanded, further coupled with the vernier effect of the cascaded structure, the tunable range of lasers applying the resonance module provided by the embodiments of the present disclosure is greatly expanded. At the same time, in a loop of the silicon-based external cavity laser, introducing the auxiliary resonator coupled with a main resonator can maintain the narrow linewidth characteristic and tunable characteristic of silicon-based external cavity.

It can be understood that the beneficial effects of the second to fifth aspects described above can be found in the relevant description of the first aspect, which will not be further elaborated here.

### BRIEF DESCRIPTION OF DRAWINGS

In order to illustrate the technical solutions of embodiments of the present disclosure more clearly, the drawings that need to be used in the description of the embodiments of the present disclosure or the prior art will be briefly introduced in the following. Obviously, the drawings in the following description are some embodiments of the present disclosure. For those of ordinary skill in the art, other drawings can be obtained according to these drawings without paying any creative effort.

FIG. 1 is a schematic structure diagram of a silicon-based external cavity laser provided by an embodiment of the present disclosure.

FIG. 2 is a schematic structure diagram of a silicon-based external cavity laser provided by another embodiment of the present disclosure.

FIG. 3 is a schematic structure diagram of a silicon-based external cavity laser provided by another embodiment of the present disclosure.

FIG. 4 is a schematic structure diagram of a silicon-based external cavity laser provided by another embodiment of the present disclosure.

FIG. 5 is a schematic structure diagram of an auxiliary resonator adopted by an embodiment of the present disclosure.

FIG. 6 is a schematic structure diagram of a silicon-based external cavity laser provided by another embodiment of the present disclosure.

FIG. 7 is a schematic diagram of the transmissivity of a first main resonator, a second main resonator, and an auxiliary resonator adopted in an embodiment of the present disclosure. In the illustrative drawing, a first micro-ring resonator represents the first main resonator, a second micro-ring resonator represents the second main resonator, and an auxiliary micro-ring resonator represents the auxiliary resonator.

FIG. 8 is a schematic diagram of the transmissivity of a first main resonator, a second main resonator, a third main resonator, and an auxiliary resonator adopted in an embodiment of the present disclosure. In the illustrative drawing, a first micro-ring resonator represents the first main resonator, a second micro-ring resonator represents the second main resonator, a third micro-ring resonator represents the third main resonator, and an auxiliary micro-ring resonator represents the auxiliary resonator.

FIG. 9A and FIG. 9B are comparison diagrams of a reflectivity map of an external cavity photon loop corresponding to a silicon-based external cavity laser utilizing a vernier effect of two resonators in the prior art and a reflectivity map of an external cavity photon loop corresponding to a silicon-based external cavity laser provided by an embodiment of the present disclosure, where FIG. 9A is the reflectivity map of the external cavity photon loop corresponding to the silicon-based external cavity laser utilizing the vernier effect of two resonators in the prior art, and FIG. 9B is the reflectivity map of the external cavity photon loop corresponding to the silicon-based external cavity laser including a first main resonator, a second main resonator and an auxiliary resonator provided by the embodiment of the present disclosure.

FIG. 10A and FIG. 10B are comparison diagrams of a reflectivity map of an external cavity photon loop corresponding to a silicon-based external cavity laser utilizing a vernier effect of two resonators in the prior art and a reflectivity map of an external cavity photon loop corresponding to a silicon-based external cavity laser provided by an embodiment of the present disclosure, where FIG. 10A is the reflectivity map of the external cavity photon loop corresponding to the silicon-based external cavity laser utilizing the vernier effect of two resonators in the prior art, and FIG. 10B is the reflectivity map of the external cavity photon loop corresponding to the silicon-based external cavity laser including three main resonators cascaded in sequence provided by the embodiment of the present disclosure.

FIG. 11A and FIG. 11B are comparison diagrams of a reflectivity map of an external cavity photon loop corresponding to a silicon-based external cavity laser utilizing a vernier effect of two resonators in the prior art and a reflectivity map of an external cavity photon loop corresponding to a silicon-based external cavity laser provided by an embodiment of the present disclosure, where FIG. 11A is the reflectivity map of the external cavity photon loop corresponding to the silicon-based external cavity laser utilizing the vernier effect of two resonators in the prior art, and FIG. 11B is the reflectivity map of the external cavity photon loop corresponding to the silicon-based external cavity laser including a cascaded structure of three main resonators cascaded in sequence and an auxiliary resonator provided by the embodiment of the present disclosure.

### BRIEF DESCRIPTION OF REFERENCE SIGNS

100: silicon-based external cavity chip; 110: input coupler; 120: directional coupler; 121: first port; 122: second port; 123: third port; 124: fourth port; 131: first main resonator; 132: second main resonator; 133: third main resonator; 140: Sagnac ring; 150: auxiliary resonator; 160: output coupler; 170: waveguide; 180: connection module; 181: waveguide; 182: main resonator; 190: phase shifter; 200: light source.

### DESCRIPTION OF EMBODIMENTS

Embodiments of the present disclosure are described in detail in the below, examples of the embodiments are shown in the accompanying drawings, where identical or similar reference signs throughout represent identical or similar components or components with identical or similar functions. The embodiments described in the below with reference to the accompanying drawings are exemplary and intended to explain the present disclosure, but cannot be understood as limitations to the present disclosure.

In the description of the present disclosure, it should be understood that orientations or position relationships indicated by terms “length”, “width”, “up”, “down”, “front”, “back”, “left”, “right”, “vertical”, “horizontal”, “top”, “bottom”, “inside”, “outside”, etc. are orientations or position relationships based on the orientation or position relationship shown in the drawings, which is only for the convenience of describing the present disclosure and simplifying the description, and does not indicate or imply that an apparatus or an element referred to must have a specific orientation or be constructed and operated in a specific orientation, and therefore, cannot be understood as a limitation of the present disclosure.

In addition, terms “first” and “second” aims only to be used for description and cannot be understood as indicating or implying relative importance or indicating a quantity of technical features implicitly. Therefore, features limited with “first” and “second” can explicitly or implicitly include one or more of these features. In the description of the present disclosure, “multiple” means two or more than two, unless otherwise limited specifically.

In the present disclosure, unless otherwise specified and limited, terms “installation”, “link”, “connection”, “fixation” and other terms should be broadly understood, for example, they can be fixed connections, detachable connections, or integrated; they can be mechanical connections or electrical connections; they can be directly connection or indirectly connection through an intermediate medium, they can be an internal connection of two components or an interaction relationship between two components. For those of ordinary skill in the art, specific meanings of the terms described above in the present disclosure can be understood based on specific circumstances.

In order to make the purpose, technical solution, and advantages of the present disclosure clearer and understandable, the present disclosure will be further explained in detail in conjunction with the accompanying drawings and embodiments in the below.

A laser radar generally includes a transmission module and a detection module. The transmission module includes a laser source and a transmission optical system. Depending on the type of the laser source, different lasers can be adopted, such as a gas laser, a solid-state laser, a semiconductor laser, a dye laser, etc. Among them, the semiconductor laser is widely used in current optical communication systems due to its advantages of small size, easy integration, simple structure, and easy modulation. However, an ordinary semiconductor laser has defects such as poor spectral stability and large spectral linewidth, which limit its application in a complex optical communication system. An external cavity semiconductor laser, due to its advantages such as narrow linewidth, wide wavelength tunable range, small chirp, and excellent spectral characteristics, can be well applied in the complex optical communication system, such as a dense wavelength division multiplexing communication system and a coherent optical communication systems.

Specifically, the external cavity semiconductor laser is formed by setting some optical feedback elements outside a semiconductor laser to create an external cavity between a rear reflection surface of the semiconductor laser and the optical feedback elements. External cavity semiconductors laser have two typical structures, among which silicon-based narrow linewidth external cavity lasers have better performance due to their combination of a wide tunable characteristic and a narrow linewidth characteristic of external cavity structures, as well as low power consumption and high reliability characteristics of monolithic integrated structures.

A silicon-based external cavity laser is mainly consists of two parts, includes a light source and a silicon-based external cavity chip, where the light source is generally efficiently coupled with the silicon-based external cavity chip through a coupler to achieve integrated integration. The silicon-based external cavity chip also includes a resonance module, where the resonance module includes at least one main resonator. A linewidth of a laser is usually related to a cavity length of the main resonator. By increasing the cavity length of the main resonator, the linewidth can be narrowed. However, this operation will increase a quantity of longitudinal modes of lasing within the main resonator, reduce a gain difference between respective longitudinal modes, and thus cause the problem of multimode lasing. Therefore, obtaining stable single mode lasing and narrow linewidth becomes more difficult. In order to effectively avoid the above problems, in the silicon-based external cavity laser, a micro-ring resonator (MRR) with high Q-factor are usually selected for frequency selection and mode locking, because the MRR has a wide free spectral range (FSR, Free Spectral Range), and the MRR essentially increases the effective cavity length, thereby improving photon lifetime, achieving linewidth narrowing and suppression of phase noise and relative intensity noise. In addition, the vernier caliper effect of MRR can also be utilized to achieve tuning over a wide wavelength range.

However, for current silicon-based external cavity lasers, as mentioned above, their tunable range still need to be further expanded while maintaining a narrow linewidth and a high side-mode suppression ratio. Regarding the above issues, the embodiments of the present disclosure provide a resonance module, where the resonance module can utilize the coupling effect of the micro-ring combined with the vernier effect, so that the tunable range of the silicon-based external cavity laser applying the resonance module can be further expanded while maintaining a narrow linewidth and a high side-mode suppression ratio. This expands the original tunable range in the tunable range of the C-band laser to a wider working range, increasing the application range and prospects of the silicon-based external cavity laser.

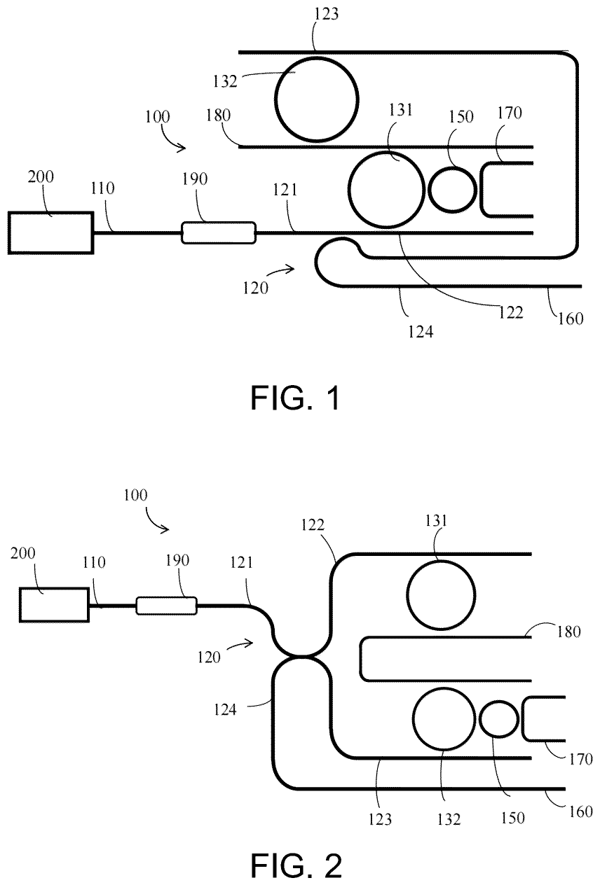

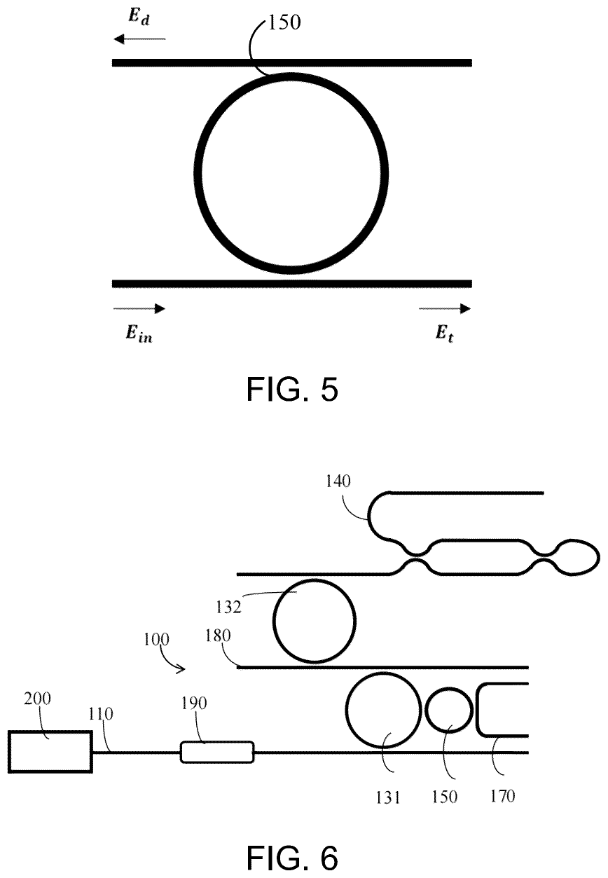

Please refer to what is shown in FIG. 1 to FIG. 4, the resonance module includes multiple main resonators and at least one auxiliary resonator 150, where both of the main resonators and the auxiliary resonator 150 are tunable micro-ring resonators; the multiple main resonators are cascaded in sequence through a connecting module 180 to form a cascaded structure, and a vernier effect can be formed between two adjacent main resonators. When an auxiliary resonator 150 is provided for matching the main resonator, coupling of the main resonator and the auxiliary resonator 150 that are provided in a matching manner expands a free spectrum range of the main resonator. The auxiliary resonator 150 in this embodiment may adopt an upload-download structure as shown in FIG. 5, one port of the auxiliary resonator 150 is connected with a corresponding main resonator in this case, the other port is coupled with a waveguide 170, as shown in FIG. 1 to FIG. 4; the auxiliary resonator 150 may also adopt a single waveguide coupling structure, the auxiliary resonator 150 is directly connected with a corresponding main resonator without the waveguide 170 in this case. The auxiliary resonator 150 shown in FIG. 5 is similar to a single ring upload-download resonator, specifically, when the single ring upload-download resonator is adopted, the optical signal enters into this resonator via an Eᵢₙ terminal; after the processing in the resonator (150), part of the optical signal conformed with corresponding requirements is left and enters into the waveguide (170) or a main resonator (such as the main resonator 131) via an E_{d} terminal, part of the optical signal not conformed with corresponding requirements is filtered out (for example, transmitted out via an Eₜ terminal).

The multiple main resonators being cascaded in sequence through a connecting module 180 to form a cascaded structure refers to that, the multiple main resonators are provided in sequence, any two adjacent main resonators are optically connected through one connecting module 180.

The main resonator having an auxiliary resonator 150 is provided for matching the main resonator refers to that, at least one main resonator has an auxiliary resonator 150 to match itself. Here, the matching refers to that the coupling can be implemented between the two, and the expansion of the free spectrum range of the main resonator can be achieved through their mutual coupling of the two. It can be understood that in the resonance module, an auxiliary resonator can be provided for matching only one main resonator, or corresponding auxiliary resonators can be provided for matching multiple main resonators respectively, and usually one auxiliary resonator is provided for matching one main resonator.

In one embodiment, the cascaded structure is a two-level cascaded structure, which includes a first main resonator, a second main resonator and an auxiliary resonator; where the auxiliary resonator is provided to match with the first main resonator.

There is a length difference between a cavity length of the first main resonator and a cavity length of the second main resonator, and the cavity length of the first main resonator and the cavity length of the second main resonator are both integer multiples of the length difference mentioned above. A free spectrum range of the auxiliary resonator is twice as much as a free spectrum range of the first main resonator.

For the convenient of understanding, the principle of the resonance module provided by an embodiment of the present disclosure is now illustrated by taking the example that the main resonators are provided with two, where a first level main resonator in the cascaded structure is the first main resonator 131, a second level main resonator in the cascaded structure is the second main resonator 132, and the auxiliary resonator 150 is provided to match the first main resonator 131.

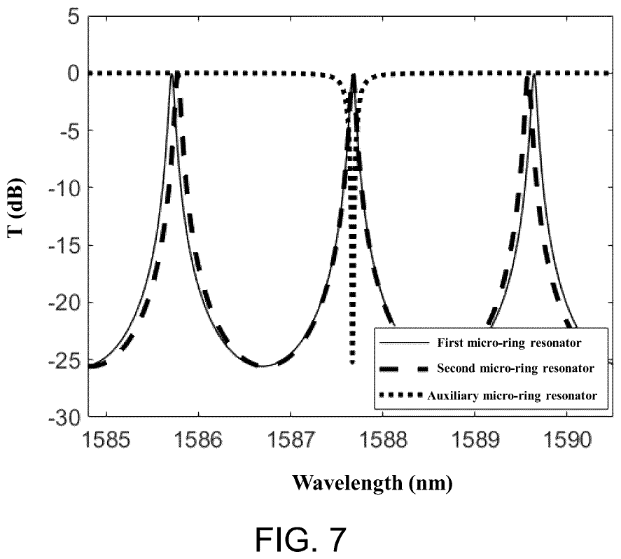

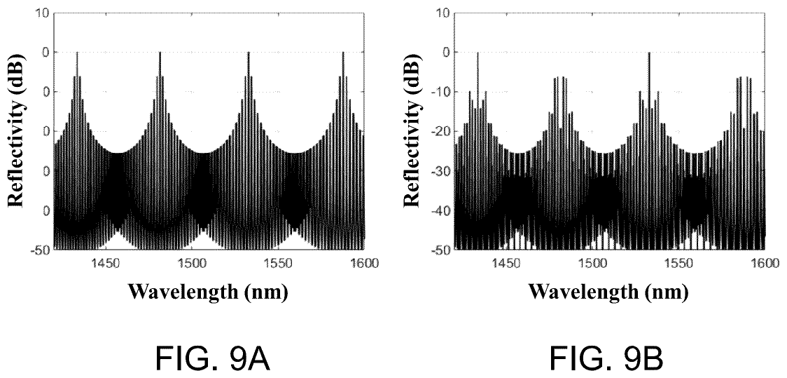

Please refer to FIG. 1, FIG. 2, FIG. 7, FIG. 9A and FIG. 9B, all resonators mentioned in this embodiment include the first main resonator 131, the second main resonator 132, and the auxiliary resonator 150, where the free spectrum range of any resonator satisfies the following formula:

$$FSR = Δ λ = \frac{{λ}^{2}}{{n}_{g} L} ,$$

where λ is a resonance wavelength of the resonator, Δλ is a wavelength gap between adjacent resonance modes of the resonators, n_{g} is a group refractive index of a waveguide of the resonator, L is a cavity length of the resonator.

There is a length difference between a cavity length of the first main resonator 131 and a cavity length of the second main resonator 132, and the cavity length of the first main resonator 131 and the cavity length of the second main resonator 132 are both integer multiples of the length difference, therefore, the vernier effect of the micro-ring resonator can be utilized to expand the free spectrum range of the whole external cavity, and the free spectrum range and the resonance mode of the main resonator can be shifted through a thermal tuning, to achieve the purpose of selecting a laser wavelength to be output. FSR of the external cavity after the vernier effect is:

$${FSR}_{External cavity} = \vert \frac{{FSR}_{1} \cdot {FSR}_{2}}{{FSR}_{2} - {FSR}_{1}} \vert ,$$

where FSR₁ and FSR₂ are respectively the free spectrum range of the first main resonator 131 and the free spectrum range of the second main resonator.

The auxiliary resonator 150 is coupled with the first main resonator 131, when the cavity length of the auxiliary resonator 150 is half of the cavity length of the first main resonator 131, FSR₃=2FSR₁, where FSR₃ is a free spectrum range of the auxiliary resonator 150; due to that the first main resonator 131 is coupled with the auxiliary resonator 150, resonance modes with equal wavelengths will couple with each other to cause mode splitting, so that a resonance mode that could have been selected as laser outputs by the vernier effect is annihilated. However, since FSR₃=2FSR₁, it means that every other resonance mode selected as laser output will be annihilated due to the coupling effect. Therefore, in this case, the FSR of the external cavity based on the coupling effect and the vernier effect is:

$${FSR}_{External cavity} = 2 \vert \frac{{FSR}_{1} \cdot {FSR}_{2}}{{FSR}_{2} - {FSR}_{1}} \vert .$$

Therefore, adopting the resonance module described above can achieve the effect of expanding the tunable range by twice. In addition, due to that FSR is not only related to the cavity length of the resonator, but also to the refractive index, the wavelength, etc., the FSR of the main resonator can be extended through other means.

When the main resonators are provided with two or more and the auxiliary resonators 150 are provided with multiple, not only the tunable range of the laser can be expanded, but also the side-mode suppression ratio of the laser can be further improved.

In summary, the resonance module provided by the embodiment of the present disclosure includes multiple main resonators and at least one auxiliary resonator, the multiple main resonators are cascaded in sequence through a connecting module to form a cascaded structure, and a vernier effect can be formed between two adjacent main resonators; when the an auxiliary resonator is provided for matching the main resonator, utilizing the coupling of the main resonator and the auxiliary resonator that are provided in a matching manner, a free spectrum range of the main resonator can be expanded, and the tunable range of laser may be greatly expanded based on the vernier effect formed between two adjacent main resonators. At the same time, in a loop of the silicon-based external cavity laser, introducing the auxiliary resonator 150 coupled with the main resonator can maintain the narrow linewidth characteristic and tunable characteristic of silicon-based external cavity.

Please refer to what is shown in FIG. 1 to FIG. 3, in some embodiments, the cascaded structure is a two-level cascaded structure including a first main resonator 131 and a second main resonator 132; the auxiliary resonator 150 is provided with one and is provided for matching the first main resonator 131; there is a length difference between a cavity length of the first main resonator and a cavity length of the second main resonator, and the cavity length of the first main resonator and the cavity length of the second main resonator are both integer multiples of the length difference; a free spectrum range of the auxiliary resonator is twice as much as a free spectrum range of the first main resonator.

The resonance module adopts the structure provided by this embodiment, which can achieve the effect of expanding the tunable range by twice, and the structure of the resonance module is simple and easy to assemble.

Many solutions can be adopted to make sure that the free spectrum range of the auxiliary resonator is twice as much as the free spectrum range of the first main resonator mentioned. In an embodiment, the cavity length of the auxiliary resonator is ½ of the cavity length of the first main resonator, that can achieve the effect of expanding the tunable range by twice, and the structure of the resonance module is simple and easy to assemble.

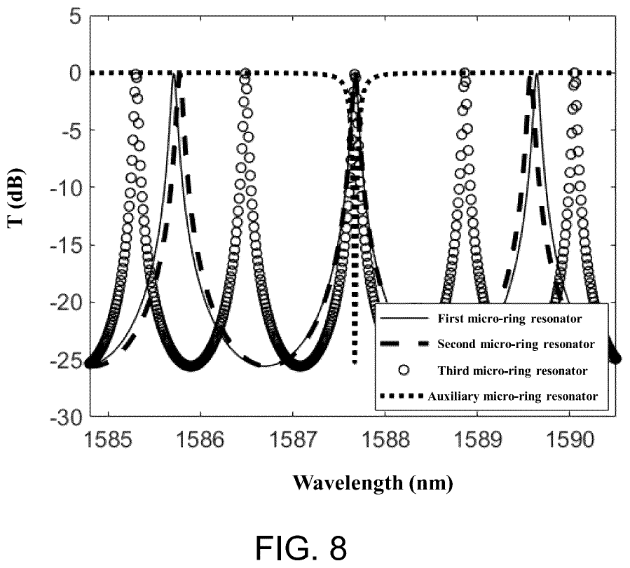

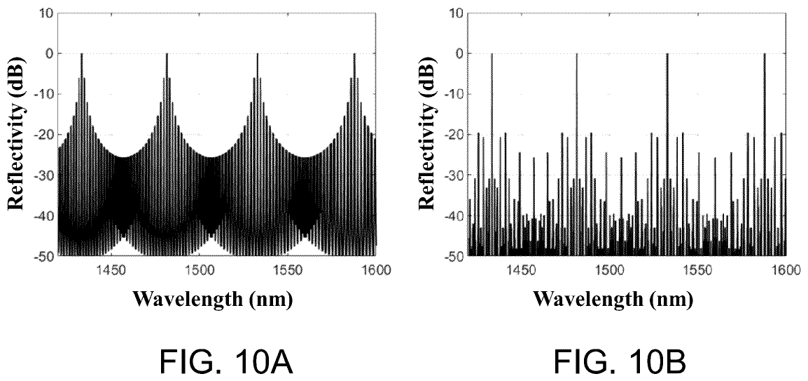

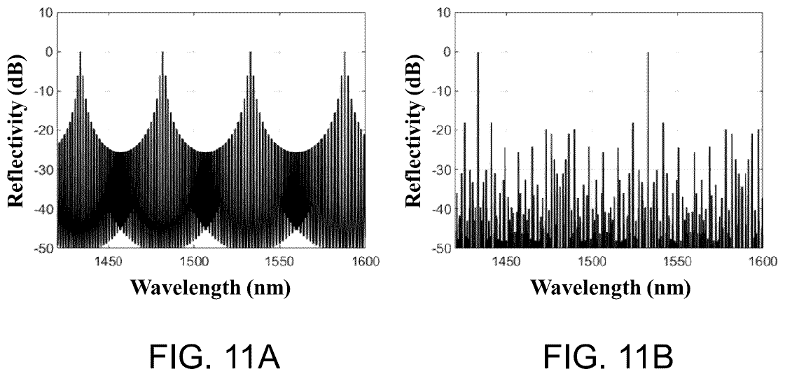

Please refer to what is shown in FIG. 4, FIG. 8, FIG. 10A, FIG. 10B, and FIG. 11A and FIG. 11B, in some embodiments, the cascaded structure is a cascaded structure formed by 3 or more of the main resonators being cascaded in sequence, length differences between cavity lengths of every two adjacent main resonators are different. Adopting the solution provided by this embodiment, the vernier effect of three or more micro-ring resonators can be utilized to expand the free spectrum range of the whole external cavity and to improve the side-mode suppression ratio, and the free spectrum range and the resonance mode of the main resonator can be shifted by thermal modulation, to achieve the purpose of selecting a laser wavelength to be output.

Comparing with the two-level cascaded structure, the resonance module in this embodiment has simpler structure, and it is beneficial to improve the side-mode suppression ratio, so that the silicon-based external cavity maintains narrow linewidth, high side-mode suppression ratio, and wide tunable characteristics.

When the cascaded structure is an N level (N is an integer greater than 1) cascaded structure, the resonance module receives two input light beams from an external input. One input light beam enters into the resonance module through an input port of a first level main resonator, and after passing through the N main resonators in sequence, is coupled out from the resonance module by an download port of an Nth level main resonator; the other input light beam is inputted into the resonance module through the download port of the Nth level main resonator, and after passing through the N main resonators in sequence, is coupled out from the resonance module by the input port of the first level main resonator.

The cascaded structure in this embodiment can achieve bidirectional transmission of light beams. In this way, when designing the loop, only the input/output structures of the optical path are set at both ports of the cascaded structure, the closure of the entire optical path can be achieved. There is no need to set a loop structure outside the cascaded structure, making the structure of the entire resonance module simple and easy to design and assemble.

The connection module 180 can be set up in a multiple of manners, which can be flexibly selected according to usage requirement.

Please refer to what is shown in FIG. 1 and FIG. 2, in some embodiments, the connecting module 180 includes a waveguide. The waveguide may be a straight waveguide or a curved waveguide. When the connecting module adopts the straight waveguide or the curved waveguide, the structure is simple and easy to fabricate.

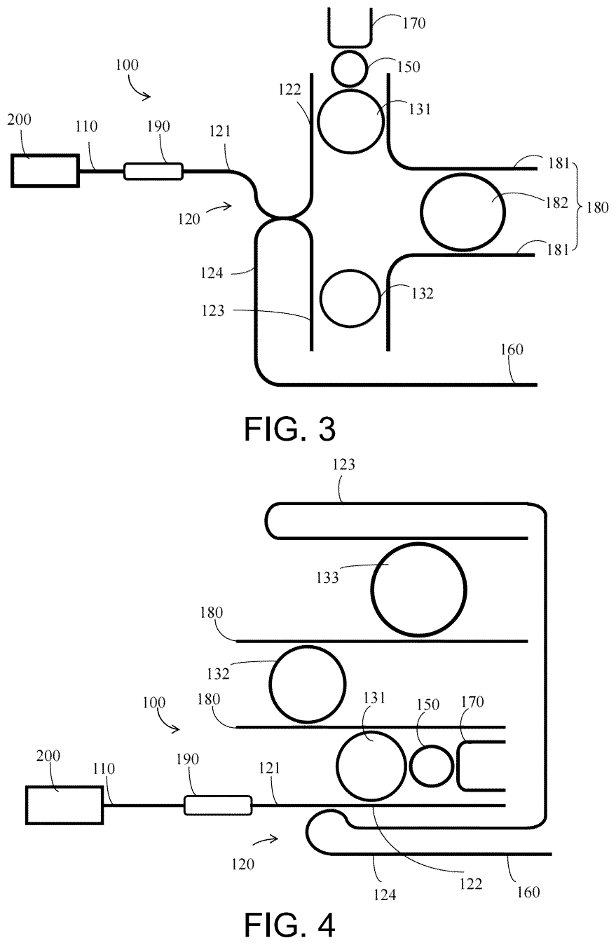

Please refer to what is shown in FIG. 3, in some other embodiments, the connecting module 180 includes a combination structure of a waveguide 181 and one main resonator 182. The main resonator 182 is connected with a corresponding main resonator through the waveguide 181. The corresponding main resonator refers to a main resonator adjacent to the main resonator 182. The waveguide 181 may adopt the straight waveguide or the curved waveguide according to usage requirement.

There is a length difference between a cavity length of the main resonator 182 and a cavity length of the adjacent main resonator, so that the vernier effect can be formed between the main resonator 182 and the adjacent main resonator, to further improve the side-mode suppression ratio.

Please refer to what is shown in FIG. 1 to FIG. 4, an embodiment of the present disclosure provide a silicon-based external cavity chip 100, which includes an input coupler 110, a directional coupler 120, a resonance module and an output coupler 160. The resonance module is a resonance module provided by any embodiment described above.

The input coupler 110 is configured to couple a light signal provided by an external light source 200 into the silicon-based external cavity chip 100.

The directional coupler 120 receives the light signal and provides the light signal to the resonance module, the light signals is selected by the resonance module, the selected light signal is coupled out through the directional coupler 120 and the output coupler 160 in sequence. The directional coupler 120 in this embodiment may be a 2*2 coupler, or a 3*2 coupler, or an M*N star coupler, as long as it can achieve corresponding functions.

The silicon-based external cavity chip 100 provided by an embodiment of the present disclosure adopts the resonance module provided by any embodiment described above, the vernier effect of the silicon-based external cavity laser can greatly expand the tunable range of lasers, and can maintain the narrow linewidth characteristic and tunable characteristic of silicon-based external cavity.

In some embodiments, the directional coupler 120 includes a first port 121, a second port 122, a third port 123, and a fourth port 124. The first port 121 is connected to an output port of the input coupler 110 through optical path, the second port 122 is connected to a first port of the resonance module through optical path, the third port 123 is connected to a second port of the resonance module through optical path, and the fourth port 124 is connected to an input port of the output coupler 160 through optical path. Specifically, the directional coupler 120 may be a 2×2 directional coupler.

The light signal received by the first port 121 of the directional coupler 120 are divided into two input light beams in the directional coupler 120. One input light beam is coupled into the resonance module through the second port 122 of the directional coupler 120 and the first port of the resonance module in sequence, is coupled into the directional coupler 120 through the second port of the resonance module and the third port 123 of the directional coupler 120 after passing through a cascaded structure of the resonance module, and is provided to the output coupler 160 by the fourth port 124 of the directional coupler 120 after passing through the directional coupler; the other input light beam is coupled into the resonance module through the third port 123 of the directional coupler 120 and the second port of the resonance module in sequence, is coupled into the directional coupler 120 through the first port of the resonance module and the second port 122 of the directional coupler 120 after passing through the cascaded structure of the resonance module, and is provided to the output coupler 160 by the fourth port 124 of the directional coupler 120.

For the convenience of description, by taking the resonance module shown in FIG. 1 for example, the operation principle of the silicon-based external cavity laser of the silicon-based external cavity chip 100 is illustrated. The resonance module includes a first main resonator 131 and a second main resonator 132, and the auxiliary resonator 150 is provided with one and is couple with the first main resonator 131:
a light source emits light signals, which are coupled into the silicon-based external cavity chip 100 through the input coupler 110. After that, the light signals enter into the directional coupler 120 via the first port 121, and then be divided into two beams by the directional coupler 120, where one beam is coupled into the resonance module through the second port 122, the other beam is coupled into the resonance module through the third port 123.

The light signals entered into the resonance module via the second port 122 firstly propagate within the first main resonator 131. After that, due to that the first main resonator 131 is coupled with the auxiliary resonator 150, resonance modes with equal wavelengths will couple with each other to cause mode splitting, so that a resonance mode that could have been selected as a laser output by the vernier effect is annihilated, that is, the light signals of some wavelengths are filtered out; when the remaining light signals pass through a connection area of the first main resonator 131 and the connection module 180, they are transmitted to the inside of the connection module 180, and then transmitted to the second main resonator 132 through the connection module 180. After that, they are output via a download port of the second main resonator 132 and enter into the directional coupler 120 through the third port 123.

The light signals entered into the resonance module via the third port 123 firstly propagate within the second main resonator 132, then enter into the first main resonator 131 via the connecting module 180. After that, due to that the first main resonator 131 is coupled with the auxiliary resonator 150, the resonance modes with equal wavelengths will couple with each other to cause mode splitting, so that the resonance mode that could have been selected as a laser output by the vernier effect is annihilated, that is, the light signals of some wavelengths are filtered out; the remaining light signals is output through the first main resonator 131 and enter into the directional coupler 120 through the second port 122.

After that, the light signals entered into the directional coupler 120 are divided into two beams via the directional coupler 120 again. One beam is output via the first port 121 and the input coupler 110 and fed back to the external light source, to form a loop; the other beam couples out from the silicon-based external cavity 100 via the fourth port 124 and the input coupler 160.

The silicon-based external cavity 100 provided by this embodiment has a simple structure and is easy to assemble.

Regardless of which structure of the resonance module mentioned above is adopted, the above effect can be achieved. In the above embodiments, relying solely on each main resonator for frequency modulation and wavelength adjustment often cannot achieve optimal output light. Therefore, in some embodiments, as shown in FIG. 1 to FIG. 4, the silicon-based external cavity chip 100 further includes a phase shifter 190 connected between the input coupler 110 and the first port of the directional coupler 120. The phase shifter 190 is mainly used for frequency modulation and fine wavelength adjustment to optimize the performance of the output light.

The phase shifter mentioned above may be a thermal optical phase shifter or an electro-optical phase shifter. Among them, when the thermal optical phase shifter is adopted, it has advantages such as low power consumption and low loss, and the thermal optical phase shifter is implemented based on the thermal optical effect of silicon material. Due to the high thermal optical coefficient of the silicon material, the thermal optical modulation that completes the adjustment of silicon waveguide optical properties through temperature change of the silicon material plays an important role in silicon-based optical devices, and is particularly attractive in in the fields of low cost and low-frequency modulation. When the electro-optic phase shifter is adopted, it has the characteristics of high performance and low power consumption.

The specific type of the input coupler mentioned above can be determined based on the specific type of the light source. For example, when the light source adopts a semiconductor optical amplifier (SOA), the corresponding input coupler adopts a spot-size converter; when the light source adopts a laser diode (LD) chip, the input coupler can be etched on the silicon-based external cavity chip; when the light source adopts a vertical cavity surface emitting laser, the corresponding input coupler is a grating coupler; the light source and the input coupler are bonded in the form of flip chip.

In some embodiments, both the input coupler and the output coupler adopt a spot-size converter. In this case, the external light source can adopt a semiconductor optical amplifier to fully utilize existing semiconductor laser technology and facilitate integration with other optical devices. The adoption of spot-size converters for the input coupler and the output coupler allows the spot size of a device used to connect with an external device in the silicon-based external cavity chip to be consistent with the spot size of the external device, thereby reducing coupling losses.

In order to make the coupling efficiency of the input coupler and output coupler higher, in some embodiments, the input coupler and the output coupler are respectively inverted cone type couplers or cone type couplers.

The power beam splitting ratio of the directional coupler in the embodiments mentioned above can be flexibly selected according to usage requirement. In order to make a linewidth of the optical signal output through the fourth port narrower and an output power higher, in some embodiments, the power beam splitting ratio of the directional coupler is 5:5.

Please refer to FIG. 6, in another embodiment of the present disclosure, a silicon-based external cavity chip 100 is provided, which includes an input coupler 110, a resonance module and a Sagnac ring 140. The resonance module is a resonance module provided by any embodiment described above.

The input coupler 110 is configured to couple a light signal provided by an external light source 200 into the silicon-based external cavity chip 100, further configured to couple a light signal fed back by the silicon-based external cavity chip 100 into the inside of the external light source 200.

A first port of the resonance module is coupled to the input coupler 110 through a waveguide, a second port of the resonance module is coupled to the Sagnac ring 140.

For the convenience of description, now as shown in FIG. 6, the operation principle of the silicon-based external cavity laser applying the silicon-based external cavity chip 100 provided by an embodiment of the present disclosure is illustrated by taking the example that the multiple main resonators in the resonance module includes a first main resonator 131 and a second main resonator 132, and the auxiliary resonator 150 is provided with one and is couple with the first main resonator 131:
a light source emits light signals, which are coupled into the silicon-based external cavity chip 100 via the input coupler 110. After that, the light signals enter into the cascaded structure, the light signals firstly propagate within the first main resonator 131. After that, due to that the first main resonator 131 is coupled with the auxiliary resonator 150, resonance modes with equal wavelengths will couple with each other to cause mode splitting, so that a resonance mode that could have been selected as a laser output by the vernier effect is annihilated, that is, the light signals of some wavelengths are filtered out; when the remaining light signals pass through a connection area of the first main resonator 131 and the connection module 180, they are transmitted to the inside of the connection module 180, and then transmitted to the second main resonator 132 through the connection module 180. After that, they are output via the second main resonator 132.

After that, the light signals enter into the Sagnac ring, and a part of it is output from the silicon-based external cavity chip through the Sagnac ring, the other part is reflected by the Sagnac ring and sequentially coupled out from the silicon-based external cavity chip 100 through the second main resonator 132, the connection module 180, the first main resonator 131, and the input coupler 110 in a reverse order.

The silicon-based external cavity chip 100 provided by the embodiments of the present disclosure adopts the resonance module provided by any embodiment described above, the tunable range of the silicon-based external cavity laser adopting the silicon-based external cavity chip 100 provided by the embodiments of the present disclosure is expanded, and can maintain the narrow linewidth characteristic and tunable characteristic of silicon-based external cavity.

Regardless of which resonance module mentioned above is adopted, the above effect can be achieved. In the above embodiments, relying solely on each main resonator for frequency modulation and wavelength adjustment often cannot achieve optimal output light. Therefore, in some embodiments, as shown in FIG. 6, the silicon-based external cavity chip 100 further includes a phase shifter 190 connected between the input coupler 110 and the resonance module. The phase shifter 190 is mainly used for frequency modulation and fine wavelength adjustment to optimize the performance of the output light.

The phase shifter mentioned above adopts a thermal optical phase shifter or an electro-optical phase shifter. Among them, when the thermal optical phase shifter is adopted, it has advantages such as low power consumption and low loss, and the thermal optical phase shifter is implemented based on the thermal optical effect of silicon material. Due to the high thermal optical coefficient of the silicon material, the thermal optical modulation that completes the adjustment of silicon waveguide optical properties through temperature change of the silicon material plays an important role in silicon-based optical devices, and is particularly attractive in in the fields of low cost and low-frequency modulation. When the electro-optic phase shifter is adopted, it has the characteristics of high performance and low power consumption.

The specific type of the input coupler mentioned above can be determined based on the specific type of the light source. For example, when the light source adopts a semiconductor optical amplifier (SOA), the corresponding input coupler adopts a spot-size converter; when the light source adopts a laser diode (LD) chip, the input coupler can be etched on the silicon-based external cavity chip; when the light source adopts a vertical cavity surface emitting laser, the corresponding input coupler is a grating coupler; the light source and the input coupler are bonded in the form of flip chip.

In some embodiments, the input coupler adopts a spot-size converter. In this case, the external light source can adopt a semiconductor optical amplifier to fully utilize existing semiconductor laser technology and facilitate integration with other optical devices. The adoption of spot-size converters for the input coupler allows the spot size of a device used to connect with an external device in the silicon-based external cavity chip to be consistent with the spot size of the external device, thereby reducing coupling losses.

Please refer to what is shown in FIG. 1 to FIG. 6, in another embodiment of the present disclosure, a silicon-based external cavity laser is provided, which includes a light source 200 and a silicon-based external cavity chip 100 provided by a respective embodiment described above, where the light source 200 is configured to provide a light signal to the silicon-based external cavity chip 100. An input port of the input coupler 110 is coupled with an output port of the light source 200.

As mentioned above, the specific type of the input coupler 110 can be determined based on the specific type of the light source 200. The silicon-based external cavity laser in this embodiment can not only include the devices mentioned above, but also include a shell, optical fibers, etc., which can be determined according to design requirements.

The silicon-based external cavity lasers provided by the embodiments of the present disclosure adopts the silicon-based external cavity chip 100 provided by a respective embodiment described above. On the one hand, by introducing the auxiliary resonator 150 coupled with the main resonator, utilizing the coupling effect of the double micro-ring in combination with the vernier effect, the tunable range of lasers is greatly expanded; on the other hand, in a loop of the silicon-based external cavity laser, the introduction of the auxiliary resonator 150 coupled with the main resonator can maintain the narrow linewidth characteristic and tunable characteristic of silicon-based external cavity.

In some embodiments, the light source is a semiconductor optical amplifier, a port of the light source away from the silicon-based external cavity chip has a preset reflectivity. The preset reflectivity can be set according to usage requirement. If high reflectivity is required, the preset reflectivity should be ≥90%, at this time, the output port of the light source (i.e. a port near the silicon-based external cavity chip) can be coated with an anti reflective film to make it has low reflectivity, with a reflectivity ≤0.01%; if there is light emitting from this port, the preset reflectivity can adopt other values. A gain wavelength of the light source is in the communication band and can be achieved through three to five groups of quantum wells or quantum dot materials. The light source adopts the arrangement manner of this embodiment, which has a simple structure and small volume, can make full use of the existing semiconductor laser technology, has a mature production process, a low cost, a long life, a small power consumption, and is easy to be integrated with other optical devices.

In another embodiment of the present disclosure, a laser radar is provided, which includes a laser module, a transmission module, a detection module, a detection module, and a data processing module, where the laser module includes a silicon-based external cavity laser provided by any embodiment described above.

The transmission module in this embodiment can adopt existing transmission modules in the market. The detection module in this embodiment can adopt existing detection modules in the market. The data processing module in this embodiment can adopt existing data processing modules in the market. The laser radar in this embodiment can not only include the laser module, the transmission module, the detection module, and the data processing module mentioned above, but also include at least one of a shell and a scanning apparatus, which can be determined according to design requirements.

The laser radar provided in the embodiments of the present disclosure includes the silicon-based external cavity laser provided in embodiments described above. On the one hand, the tunable range of the laser is greatly expanded; on the other hand, the narrow linewidth characteristic and tunable characteristic of silicon-based external cavity can be maintained, the scanning angle of the laser radar can be effectively improved.

The above descriptions are only illustrative embodiments of the present disclosure and specifically describes the technical principles of the present disclosure. These descriptions are only intended to explain the principles of the present disclosure and cannot be interpreted in any way as limiting the protection scope of the present disclosure. Based on the explanation here, any modifications, equivalent substitutions, and improvements made within the spirit and principles of the present disclosure, as well as other specific embodiments of the present disclosure that can be associated without creative efforts by those skilled in the art, shall be included in the protection scope of the present disclosure.

What is claimed is:

1. A resonance module, comprising: multiple main resonators and at least one auxiliary resonator, wherein both of the main resonators and the auxiliary resonator are tunable micro-ring resonators;
the multiple main resonators are cascaded in sequence through a connecting module to form a cascaded structure, and a vernier effect can be formed between two adjacent main resonators;
when an auxiliary resonator is provided for matching the main resonator, coupling of the main resonator and the auxiliary resonator that are provided in a matching manner expands a free spectrum range of the main resonator.

2. The resonance module according to claim 1, wherein the cascaded structure is a two-level cascaded structure comprising a first main resonator and a second main resonator; the auxiliary resonator is provided with one and is provided for matching the first main resonator;
wherein there is a length difference between a cavity length of the first main resonator and a cavity length of the main second resonator, and the cavity length of the first main resonator and the cavity length of the second main resonator are both integer multiples of the length difference;
a free spectrum range of the auxiliary resonator is twice as much as a free spectrum range of the first main resonator.

3. The resonance module according to claim 2, wherein a cavity length of the auxiliary resonator is ½ of the cavity length of the first main resonator.

4. The resonance module according to claim 1, wherein the cascaded structure comprises 3 or more of the main resonators being cascaded in sequence, differences between cavity lengths of every two adjacent main resonators are different.

5. The resonance module according to claim 1, wherein when the cascaded structure is an N level cascaded structure, wherein N is an integer greater than 1, the resonance module receives two input light beams from an external input;
wherein one input light beam enters into the resonance module through an input port of a first level main resonator, and after passing through N main resonators in sequence, is coupled out from the resonance module by an download port of an Nth level main resonator; the other input light beam is inputted into the resonance module through the download port of the Nth level main resonator, and after passing through the N main resonators in sequence, is coupled out from the resonance module by the input port of the first level main resonator.

6. The resonance module according to claim 1, wherein the connecting module comprises: a waveguide; or a combination structure of a waveguide and one main resonator.

7. A silicon-based external cavity chip, comprising an input coupler, a directional coupler, a resonance module and an output coupler; wherein the resonance module comprises: multiple main resonators and at least one auxiliary resonator, wherein both of the main resonators and the auxiliary resonator are tunable micro-ring resonators;
the multiple main resonators are cascaded in sequence through a connecting module to form a cascaded structure, and a vernier effect can be formed between two adjacent main resonators;
when an auxiliary resonator is provided for matching the main resonator, coupling of the main resonator and the auxiliary resonator that are provided in a matching manner expands a free spectrum range of the main resonator;
wherein the input coupler is configured to couple a light signal provided by an external light source into the silicon-based external cavity chip;
the directional coupler receives the light signal and provides the light signal to the resonance module, the light signal is selected by the resonance module, the selected light signal is coupled out through the directional coupler and the output coupler in sequence.

8. The silicon-based external cavity chip according to claim 7, wherein the directional coupler is a 2×2 directional coupler;
wherein the light signal received by a first port of the directional coupler is divided into two input light beams in the directional coupler; wherein one input light beam is coupled into the resonance module through a second port of the directional coupler and a first port of the resonance module in sequence, is coupled into the directional coupler through a second port of the resonance module and a third port of the directional coupler after passing through the cascaded structure of the resonance module, and is provided to the output coupler by a fourth port of the directional coupler; the other input light beam is coupled into the resonance module through the third port of the directional coupler and the second port of the resonance module in sequence, is coupled into the directional coupler through the first port of the resonance module and the second port of the directional coupler after passing through the cascaded structure of the resonance module, and is provided to the output coupler by the fourth port of the directional coupler.

9. The silicon-based external cavity chip according to claim 8, wherein the silicon-based external cavity chip further comprises a phase shifter connected between the input coupler and the first port of the directional coupler.

10. The silicon-based external cavity chip according to claim 7, wherein the cascaded structure is a two-level cascaded structure comprising a first main resonator and a second main resonator; the auxiliary resonator is provided with one and is provided for matching the first main resonator;
wherein there is a length difference between a cavity length of the first main resonator and a cavity length of the main second resonator, and the cavity length of the first main resonator and the cavity length of the second main resonator are both integer multiples of the length difference;
a free spectrum range of the auxiliary resonator is twice as much as a free spectrum range of the first main resonator.

11. The silicon-based external cavity chip according to claim 10, wherein a cavity length of the auxiliary resonator is ½ of the cavity length of the first main resonator.

12. The silicon-based external cavity chip according to claim 7, wherein the cascaded structure comprises 3 or more of the main resonators being cascaded in sequence, differences between cavity lengths of every two adjacent main resonators are different.

13. The silicon-based external cavity chip according to claim 7, wherein when the cascaded structure is an N level cascaded structure, wherein N is an integer greater than 1, the resonance module receives two input light beams from an external input;
wherein one input light beam enters into the resonance module through an input port of a first level main resonator, and after passing through N main resonators in sequence, is coupled out from the resonance module by an download port of an Nth level main resonator; the other input light beam is inputted into the resonance module through the download port of the Nth level main resonator, and after passing through the N main resonators in sequence, is coupled out from the resonance module by the input port of the first level main resonator.

14. The silicon-based external cavity chip according to claim 7, wherein the connecting module comprises: a waveguide; or a combination structure of a waveguide and one main resonator.

15. A silicon-based external cavity chip, comprising an input coupler, a resonance module and a Sagnac ring; wherein the resonance module comprises: multiple main resonators and at least one auxiliary resonator, wherein both of the main resonators and the auxiliary resonator are tunable micro-ring resonators;
the multiple main resonators are cascaded in sequence through a connecting module to form a cascaded structure, and a vernier effect can be formed between two adjacent main resonators;
when an auxiliary resonator is provided for matching the main resonator, coupling of the main resonator and the auxiliary resonator that are provided in a matching manner expands a free spectrum range of the main resonator;
wherein the input coupler is configured to couple a light signal provided by an external light source into the silicon-based external cavity chip;
a first port of the resonance module is coupled to the input coupler through a waveguide, a second port of the resonance module is couple to the Sagnac ring.

16. The silicon-based external cavity chip according to claim 10, wherein the cascaded structure is a two-level cascaded structure comprising a first main resonator and a second main resonator; the auxiliary resonator is provided with one and is provided for matching the first main resonator;
wherein there is a length difference between a cavity length of the first main resonator and a cavity length of the main second resonator, and the cavity length of the first main resonator and the cavity length of the second main resonator are both integer multiples of the length difference;
a free spectrum range of the auxiliary resonator is twice as much as a free spectrum range of the first main resonator.

17. The silicon-based external cavity chip according to claim 16, wherein a cavity length of the auxiliary resonator is ½ of the cavity length of the first main resonator.

18. The silicon-based external cavity chip according to claim 15, wherein when the cascaded structure is an N level cascaded structure, wherein N is an integer greater than 1, the resonance module receives two input light beams from an external input;
wherein one input light beam enters into the resonance module through an input port of a first level main resonator, and after passing through N main resonators in sequence, is coupled out from the resonance module by an download port of an Nth level main resonator; the other input light beam is inputted into the resonance module through the download port of the Nth level main resonator, and after passing through the N main resonators in sequence, is coupled out from the resonance module by the input port of the first level main resonator.

19. A silicon-based external cavity laser, comprising a light source and the silicon-based external cavity chip according to claim 7, wherein the light resource is configured to provide a light signal to the silicon-based external cavity chip.

20. A laser radar, comprising a laser module, a transmission module, a detection module, and a data processing module, wherein the laser module comprises the silicon-based external cavity laser according to claim 19.
